(19) United States
(12) Patent Application Publication
(10) Pub. No.: US 2022/0195602 A1
(43) Pub. Date: Jun. 23, 2022

(54) GAS SUPPLY DEVICE FOR SUBSTRATE PROCESSING DEVICE, AND SUBSTRATE PROCESSING DEVICE

(71) Applicant: JUSUNG ENGINEERING CO., LTD., Gwangju-si, Gyeonggi-do (KR)

(72) Inventors: Jaewan LEE, Gwangju-si, Gyeonggi-do (KR); YongHyun KIM, Gwangju-si, Gyeonggi-do (KR); YoonJeong KIM, Gwangju-si, Gyeonggi-do (KR); YunHoe KIM, Gwangju-si, Gyeonggi-do (KR); ChangKyun PARK, Gwangju-si, Gyeonggi-do (KR)

(21) Appl. No.: 17/603,571

(22) PCT Filed: May 25, 2020
(86) PCT No.: PCT/KR2020/006743

§ 371 Date: Oct. 13, 2021

(30) Foreign Application Priority Data
Jul. 3, 2019 (KR) 10-2019-0079764

(51) Int. Cl. C23C 16/455; H01L 21/67

(52) U.S. Cl. CPC C23C 16/45574; H01L 21/67017

(57) ABSTRACT

The present inventive concept relates to a gas supply device for a substrate processing device, and a substrate processing device, wherein the gas supply device comprises: a first gas supply part for supplying a first gas to a chamber which provides a process space for a substrate; a second gas supply part for supplying, to the chamber, a second gas having a vapor pressure that is greater than the first gas; a first carrier supply part for supplying a first carrier gas to the first gas supply part such that the flow force of the first gas increases; and a second carrier supply part for supplying a second carrier gas to the second gas supply part such that the flow force of the second gas increases.

### TECHNICAL FIELD

The present disclosure relates to a substrate processing apparatus which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc. Such a processing process is performed on a substrate by a substrate processing apparatus.

A gas supply apparatus for substrate processing apparatus is used for performing the processing process. The gas supply apparatus for substrate processing apparatus include a plurality of gas supply units which distribute and inject a certain process gas into a chamber. Each of the gas supply units may distribute and inject one gas selected from among a source gas and a reactant gas, thereby performing a processing process such as depositing a certain thin film layer on the substrate.

Here, a conventional gas supply apparatus for substrate processing apparatus is insufficient in flow rate of a process gas reaching the chamber among a process gas emitted from the gas supply unit due to a low vapor pressure of a process gas. Due to this, in the conventional gas supply apparatus for substrate processing apparatus, the amount of process gas used for the processing process is decreased. Also, since a process gas is insufficient, the quality of a thin film layer of the substrate which has undergone the processing process is degraded.

### DISCLOSURE

### Technical Problem

The present inventive concept is devised to solve the above-described problem and is for providing a gas supply apparatus for substrate processing apparatus and a substrate processing apparatus, which may increase a flow rate of a process gas reaching a chamber.

### Technical Solution

To accomplish the above-described object, the present inventive concept may include the following elements.

A substrate processing apparatus according to the present inventive concept may include: a chamber providing a process space for a substrate; a first gas supply unit for supplying the chamber with a first gas having a first vapor pressure; a second gas supply unit for supplying the chamber with a second gas having a second vapor pressure which is higher than the first vapor pressure; and a third gas supply unit for supplying the chamber with a third gas having a third vapor pressure which is higher than the second vapor pressure.

A gas supply apparatus for substrate processing apparatus according to the present inventive concept may include: a first gas supply unit for supplying a first gas to a chamber providing a process space for a substrate; a second gas supply unit for supplying the chamber with a second gas having a vapor pressure which is higher than the first gas; a first carrier gas supply unit supplying a first carrier gas to the first gas supply unit to increase a flow force of the first gas; and a second carrier gas supply unit supplying a second carrier gas to the second gas supply unit to increase a flow force of the second gas, wherein the first carrier gas supply unit may supply the first carrier gas so that the first carrier gas is supplied to the first gas supply unit at a flow rate which is higher than the second carrier gas, and the first gas supply unit may be apart from the chamber by a longer distance than a distance by which the second gas supply unit is apart from the chamber. A gas supply apparatus for substrate processing apparatus according to the present inventive concept may include: N (where N is an integer of 3 or more) number of gas supply units supplying process gases having different vapor pressures to a chamber providing a process space for a substrate; and N number of carrier gas supply units respectively supplying a carrier gas to the gas supply units to increase flow forces of the process gases, wherein a first gas supply unit of the N gas supply units may supply the chamber with a first gas, having a vapor pressure which is lower than a second gas supply unit of the N gas supply units, and may be apart from the chamber by a distance which is longer than the second gas supply unit, and a first carrier gas supply unit of the N carrier gas supply units may supply the first gas supply unit with a first carrier gas having a flow rate which is higher than a second carrier gas supply unit of the N carrier gas supply units.

### Advantageous Effect

According to the present inventive concept, the following effects may be obtained.

The present inventive concept may be implemented to increase the amount of process gas used for a processing process, thereby enhancing the quality of a thin film layer of the substrate which has undergone the processing process.

The present inventive concept may be implemented to increase the mixing amount of process gases in a chamber, thereby increasing the productivity of a substrate which has undergone the processing process.

The present inventive concept may be implemented to decrease a flow rate deviation of process gases reaching the chamber, thereby enhancing the uniformity of process gases used for the processing process.

### DETAILED DESCRIPTION OF THE DRAWINGS

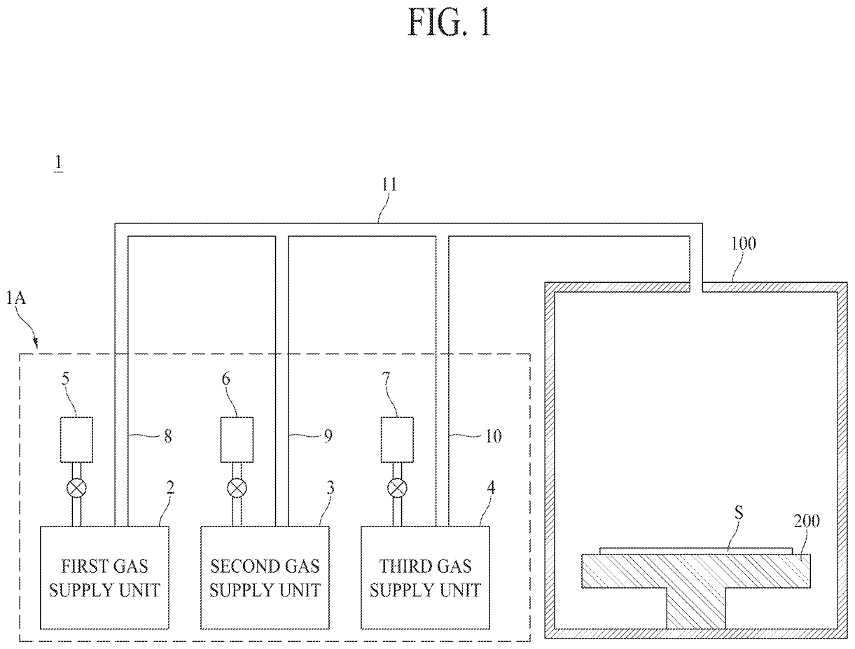

FIG. 1 is a schematic side view illustrating an embodiment of a substrate processing apparatus according to the present inventive concept.

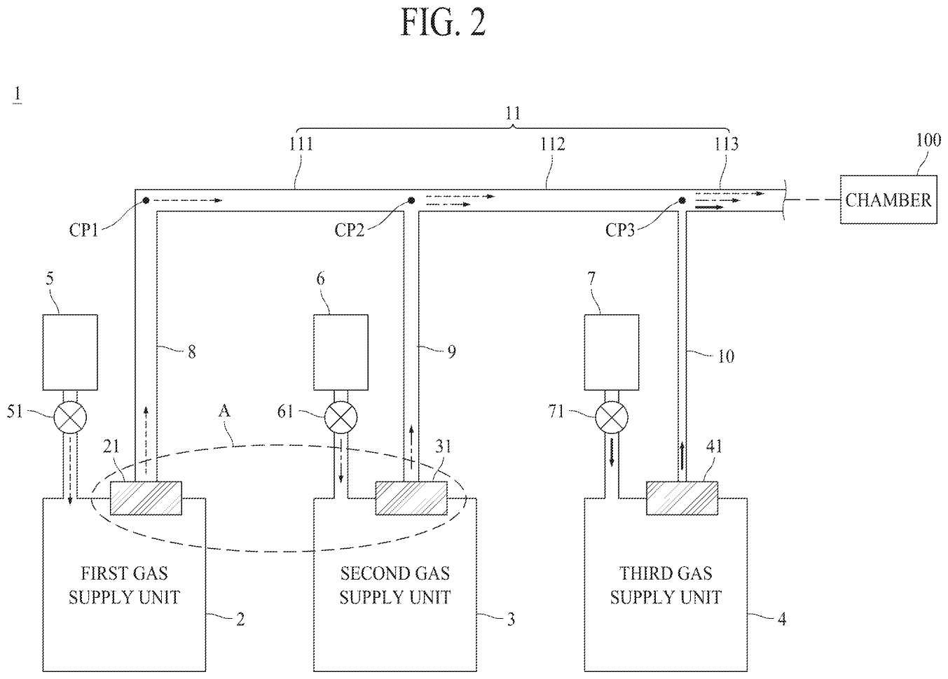

FIG. 2 is a schematic side view illustrating the enlargements of a first gas supply unit, a second gas supply unit, a third gas supply unit, a first gas flow path, a second gas flow path, and a third gas flow path in a substrate processing apparatus according to the present inventive concept.

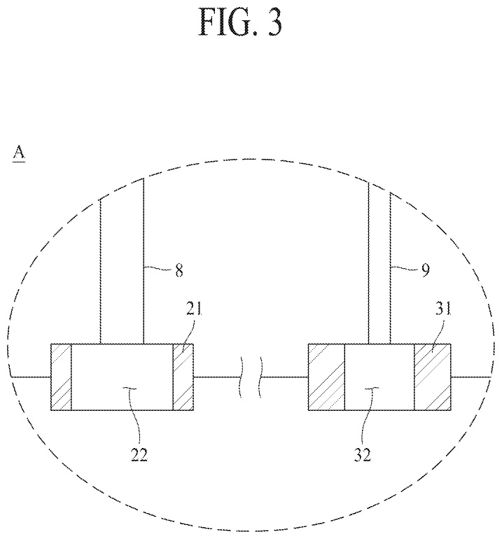

FIG. 3 is a schematic enlarged view of a portion A of FIG. 2.

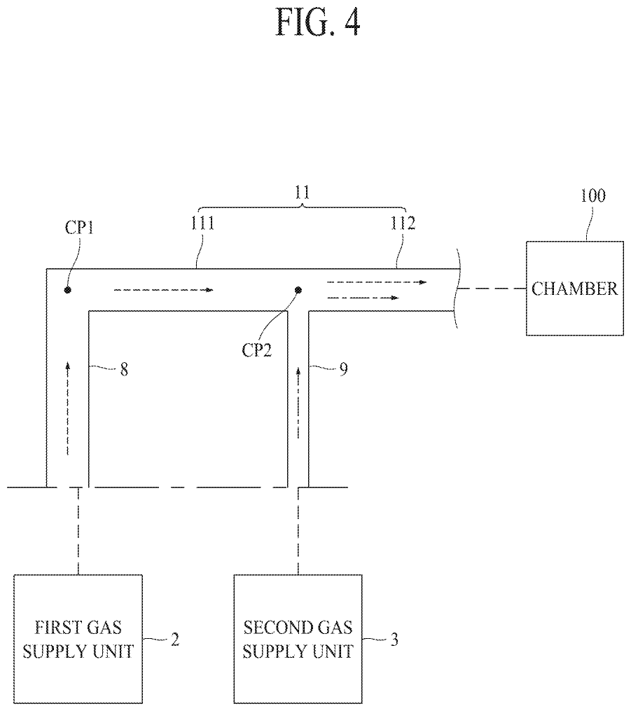

FIG. 4 is a schematic side view illustrating an embodiment where a first carrier gas flows sequentially through a first common flow path and a second common flow path, in a substrate processing apparatus according to the present inventive concept.

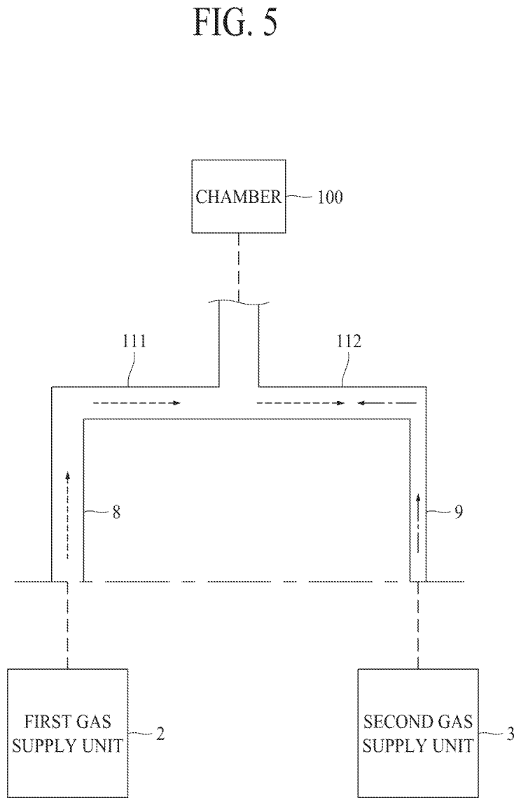

FIG. 5 is a schematic side view illustrating a comparative example where a first carrier gas does not sequentially flow through a first common flow path and a second common flow path.

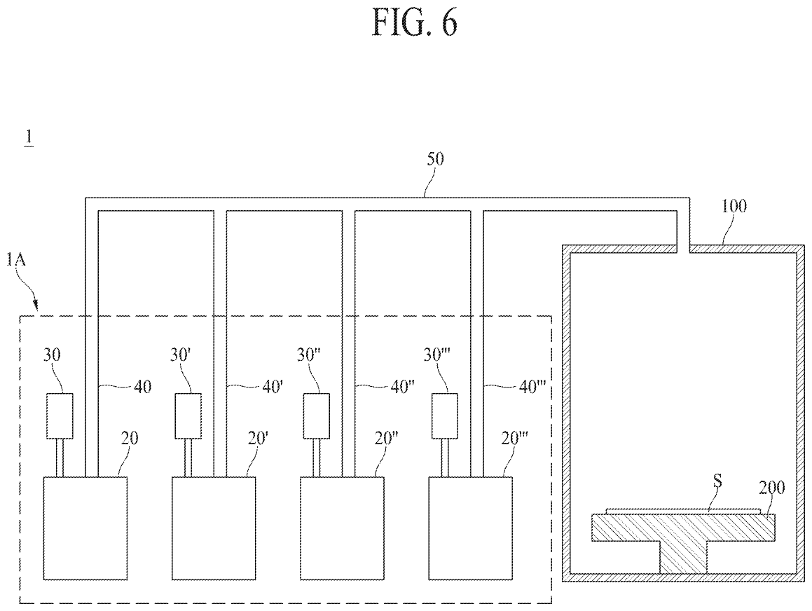

FIG. 6 is a schematic side view illustrating an embodiment where a substrate processing apparatus according to the present inventive concept includes four gas supply apparatus and four carrier gas supply units.

### DETAILED DESCRIPTION

Hereinafter, an embodiment of a substrate processing apparatus according to the present inventive concept will be described in detail with reference to the accompanying drawings. A gas supply apparatus for substrate processing apparatus according to the present inventive concept may supply a process gas used to perform a processing process on a substrate and may be included in a substrate processing apparatus according to the present inventive concept. Therefore, the gas supply apparatus for substrate processing apparatus according to the present inventive concept will be described in conjunction with describing an embodiment of the substrate processing apparatus according to the present inventive concept.

Referring to FIG. 1, a substrate processing apparatus 1 according to the present inventive concept performs a processing process on a substrate S. The substrate S may be a glass substrate, a silicon substrate, a metal substrate, or the like. The substrate processing apparatus 1 according to the present inventive concept may perform a deposition process of depositing a thin film on the substrate S and an etching process of removing a portion of a thin film deposited on the substrate S. Hereinafter, an embodiment where the substrate processing apparatus 1 according to the present inventive concept performs a deposition process will be described, but based thereon, it is obvious to those skilled in the art to deduce an embodiment where the substrate processing apparatus 1 according to the present inventive concept performs another processing process like the etching process.

Referring to FIG. 1, the substrate processing apparatus 1 according to the present inventive concept may include a chamber 100, a substrate supporting unit 200, and a gas distribution unit (not shown).

The chamber 100 provides a process space for the substrate S. As the process gas is supplied into the chamber 100, a certain deposition process using the processing gas may be performed. The chamber 100 may be implemented in a cylindrical shape which is wholly hollow, but is not limited thereto and may be implemented in a rectangular parallelepiped shape which is hollow.

The substrate supporting unit 200 supports the substrate S. The substrate supporting unit 200 may support the substrate S disposed in an inner process space of the chamber 100. The substrate supporting unit 200 may be installed in the chamber 100. The substrate supporting unit 200 may be installed in the chamber 100 to be rotatable in a certain direction. In a state where the substrate S is supported by the substrate supporting unit 200, a deposition process of depositing a certain thin film layer on the substrate S may be performed. Hatching illustrated in FIG. 1 schematically illustrates a schematic cross-sectional line of the substrate supporting unit 200 and the chamber 100.

Referring to FIG. 1, the substrate processing apparatus 1 according to the present inventive concept may include a gas supply system 1A. The gas supply apparatus for substrate processing apparatus according to the present inventive concept may be implemented to include the gas supply system 1A.

The gas supply system 1A supplies a first gas, a second gas, and a third gas to the chamber. Here, each of the first gas, the second gas, and the third gas may be a process gas used for the deposition process. The gas supply system 1A may be disposed outside the chamber 100.

The gas supply system 1A mixes a first mixed gas with a second mixed gas to supply a mixed gas to the chamber 100. Here, the first mixed gas may be a gas where the first gas is mixed with the second gas, and the second mixed gas may be a gas where the first mixed gas is mixed with the third gas. The gas supply system 1A may preferentially mix the first gas with the second gas, and sequentially, may mix the first mixed gas with the third gas. The gas supply system 1A may include the plurality of gas supply units, the plurality of carrier gas supply units, and plurality of gas flow paths through which the process gases move.

Referring to FIGS. 1 and 2, the substrate processing apparatus 1 according to the present inventive concept may include a first gas supply unit 2.

The first gas supply unit 2 is for supplying the first gas to the chamber 100. The first gas supply unit 2 may supply the first gas having a first vapor pressure to the chamber 100. As the first gas supply unit 2 supplies the first gas to the chamber 100, a processing process using the first gas may be performed in the chamber 100. The first gas may be a process gas applied to the processing process. The first gas may be a precursor included in a source material of a thin film deposited on the substrate S. For example, the first gas may include indium. The first gas may be a reactant gas which reacts with the source material.

The first gas supply unit 2 may be apart from the chamber 100. The first gas supply unit 2 may be disposed outside the chamber 100. The first gas supply unit 2 may perform a function of storing the first gas and supplying the first gas to the chamber 100. Although not shown, the first gas supply unit 2 may be supplied with the first gas from the outside through a first gas supply unit.

Referring to FIGS. 1 and 2, the substrate processing apparatus 1 according to the present inventive concept may include a second gas supply unit 3.

The second gas supply unit 3 is for supplying the second gas to the chamber 100. The second gas supply unit 3 may supply the second gas having a second vapor pressure to the chamber 100. As the second gas supply unit 3 supplies the second gas to the chamber 100, a processing process using the second gas may be performed in the chamber 100. The second gas may be a process gas applied to the processing process. The second gas may be a precursor included in a source material of a thin film deposited on the substrate S. That is, the second gas and the first gas may all be a source gas. On the other hand, the second gas and the first gas may be different gases. For example, when the first gas is a source gas, the second gas may be a reactant gas.

The second gas supplied by the second gas supply unit 3 may have a vapor pressure which is higher than that of the first gas. That is, the second vapor pressure may be higher than the first vapor pressure. For example, when the first gas includes indium, the second gas may include zinc. When the second gas has a vapor pressure which is higher than that of the first gas, the second gas may have a flow force which is greater than that of the first gas. That is, the second gas may flow by a flow distance which is longer than that of the first gas.

The second gas supply unit 3 may be apart from the chamber 100. The second gas supply unit 3 may be disposed outside the chamber 100. The second gas supply unit 3 may perform a function of storing the second gas and supplying the second gas to the chamber 100. Although not shown, the second gas supply unit 3 may be supplied with the second gas from the outside through a second gas supply unit.

The second gas supply unit 3 may be disposed closer to the chamber 100 than the first gas supply unit 2. For example, a length of a gas flow path connected from the second gas supply unit 3 to the chamber 100 may be set to be shorter than a length of a gas flow path connected from the first gas supply unit 2 to the chamber 100. That is, the first gas supply unit 2 may be disposed apart from the chamber 100 by a longer distance than a distance by which the second gas supply unit 3 is apart from the chamber 100. Accordingly, the substrate processing apparatus 1 according to the present inventive concept may be implemented so that a gas supply unit supplying a process gas having a low vapor pressure is disposed farther away from the chamber 100.

Referring to FIGS. 1 and 2, the substrate processing apparatus 1 according to the present inventive concept may include a third gas supply unit 4.

The third gas supply unit 4 is for supplying the third gas to the chamber 100. The third gas supply unit 4 may supply the third gas having a third vapor pressure to the chamber 100. As the third gas supply unit 4 supplies the third gas to the chamber 100, a processing process using the third gas may be performed in the chamber 100. The third gas may be a process gas applied to the processing process. The third gas may be a precursor included in a source material of a thin film deposited on the substrate S. That is, the third gas, the second gas, and the first gas may all be a source gas. On the other hand, the third gas may be a gas which differs from the second gas and the first gas. For example, when each of the first gas and the second gas is a source gas, the third gas may be a reactant gas.

The third gas supplied by the third gas supply unit 4 may have a vapor pressure which is higher than that of the second gas. That is, the third vapor pressure may be higher than the second vapor pressure. For example, when the first gas includes indium and the second gas includes zinc, the third gas may include gallium. In the specification, a large and small relationship between vapor pressures of the first gas, the second gas, and the third gas described as an example of a process gas may be implemented to be “first vapor pressure<second vapor pressure<third vapor pressure”. When the third gas has a vapor pressure which is higher than that of the second gas, the third gas may have a flow force which is greater than that of each of the second gas and the first gas. That is, the third gas may flow by a flow distance which is longer than that of each of the second gas and the first gas.

The third gas supply unit 4 may be apart from the chamber 100. The third gas supply unit 4 may be disposed outside the chamber 100. The third gas supply unit 4 may perform a function of storing the third gas and supplying the third gas to the chamber 100. Although not shown, the third gas supply unit 4 may be supplied with the third gas from the outside through a third gas supply unit.

The third gas supply unit 4 may be disposed closer to the chamber 100 than the second gas supply unit 3. For example, a length of a gas flow path connected from the third gas supply unit 4 to the chamber 100 may be set to be shorter than a length of a gas flow path connected from the second gas supply unit 3 to the chamber 100. That is, the second gas supply unit 3 may be disposed apart from the chamber 100 by a longer distance than a distance by which the third gas supply unit 4 is apart from the chamber 100. Accordingly, the substrate processing apparatus 1 according to the present inventive concept may be implemented so that a gas supply unit supplying a process gas having a low vapor pressure is disposed farther away from the chamber 100.

Referring to FIGS. 1 and 2, the substrate processing apparatus 1 according to the present inventive concept may include a first carrier gas supply unit 5.

The first carrier gas supply unit 5 supplies a first carrier gas to the first gas supply unit 2. The first carrier gas may be a gas for increasing a flow force of the first gas. The first carrier gas may push the first gas toward the chamber 100, and thus, may increase a flow-enabled distance of the first gas. The first carrier gas may be one gas selected from among nitrogen (N₂), argon (Ar), helium (He), and neon (Ne). The first carrier gas supply unit 5 may be connected to the first gas supply unit 2. An arrow illustrated by a dotted line in FIG. 2 schematically illustrates a schematic flow direction of the first carrier gas.

The first carrier gas supply unit 5 may be connected to the first gas supply unit 2 with being apart from the chamber 100. The first carrier gas supply unit 5 may perform a function of storing the first carrier gas and supplying the first carrier gas to the first gas supply unit 2.

Referring to FIGS. 1 and 2, the first carrier gas supply unit 5 may include a first control module 51.

The first control module 51 adjusts a flow rate of the first carrier gas. The first control module 51 may be disposed at an outlet of the first carrier gas supply unit 5. The first control module 51 may adjust a flow rate of the first carrier gas, thereby adjusting a flow force of the first gas. The first control module 51 may be wholly implemented as a valve.

Referring to FIGS. 1 and 2, the substrate processing apparatus 1 according to the present inventive concept may include a second carrier gas supply unit 6.

The second carrier gas supply unit 6 supplies a second carrier gas to the second gas supply unit 3. The second carrier gas may be a gas for increasing a flow force of the second gas. The second carrier gas may push the second gas toward the chamber 100, and thus, may increase a flow-enabled distance of the second gas. The second carrier gas may be one gas selected from among N₂, Ar, He, and Ne. The second carrier gas may be the same gas as the first carrier gas. The second carrier gas supply unit 6 may be connected to the second gas supply unit 3. An arrow illustrated by a one-dot-dashed line in FIG. 2 schematically illustrates a schematic flow direction of the second carrier gas.

The second carrier gas supply unit 6 may be connected to the second gas supply unit 3 with being apart from the chamber 100. The second carrier gas supply unit 6 may perform a function of storing the second carrier gas and supplying the second carrier gas to the second gas supply unit 3. The second carrier gas supply unit 6 may be apart from the chamber 100 by a shorter distance than the first carrier gas supply unit 5.

The second carrier gas supply unit 6 may supply the second carrier gas so that the second carrier gas is supplied to the second gas supply unit 3 at a flow rate which is lower than that of the first carrier gas. That is, the first carrier gas may flow at a flow rate which is higher than that of the second carrier gas. Accordingly, the substrate processing apparatus 1 according to the present inventive concept may realize the following effects.

First, the substrate processing apparatus 1 according to the present inventive concept may be implemented so that a flow rate of the first carrier gas is higher than that of the second carrier gas, thereby increasing a flow-enabled distance of the first gas. Therefore, the substrate processing apparatus 1 according to the present inventive concept may increase a flow rate of the first gas reaching the chamber 100, thereby increasing the amount of the first gas applied to the processing process. Accordingly, the substrate processing apparatus 1 according to the present inventive concept may enhance the quality of a thin film layer of the substrate S which has undergone the processing process.

Second, the substrate processing apparatus 1 according to the present inventive concept is implemented so that the first carrier gas increases a flow force of the first gas and the second carrier gas increases a flow force of the second gas. Therefore, the substrate processing apparatus 1 according to the present inventive concept may be implemented to increase a flow rate of each of the first gas and the second gas reaching the chamber 100 to thereby increase the mixing amount of process gases in the chamber 100. Accordingly, the substrate processing apparatus 1 according to the present inventive concept may increase the productivity of the substrate S which has undergone the processing process.

Third, the substrate processing apparatus 1 according to the present inventive concept is implemented so that a process gas having a low vapor pressure reaches the chamber 100 by using a carrier gas having a high flow rate and a process gas having a high vapor pressure reaches the chamber 100 by using a carrier gas having a low flow rate. Therefore, the substrate processing apparatus 1 according to the present inventive concept may decrease a flow rate deviation of process gases reaching the chamber 100 by using the carrier gases. Accordingly, the substrate processing apparatus 1 according to the present inventive concept may enhance the uniformity of process gases applied to the processing process.

A length of the arrow illustrated by the dotted line and a length of the arrow illustrated by the one-dot-dashed line in FIG. 2 schematically illustrate a magnitude of a flow rate of the first carrier gas and a magnitude of a flow rate of the second carrier gas, respectively.

Referring to FIGS. 1 and 2, the second carrier gas supply unit 6 may include a second control module 61. The second control module 61 adjusts a flow rate of the second carrier gas. The second control module 61 may be disposed at an outlet of the second carrier gas supply unit 6. The second control module 61 may adjust a flow rate of the second carrier gas, thereby adjusting a flow force of the second gas. The second control module 61 may be wholly implemented as a valve.

Referring to FIGS. 1 and 2, the substrate processing apparatus 1 according to the present inventive concept may include a third carrier gas supply unit 7.

The third carrier gas supply unit 7 supplies a third carrier gas to the third gas supply unit 4. The third carrier gas may be a gas for increasing a flow force of the third gas. The third carrier gas may push the third gas toward the chamber 100, and thus, may increase a flow-enabled distance of the third gas. The third carrier gas may be one gas selected from among N₂, Ar, He, and Ne. The third carrier gas may be the same gas as the second carrier gas. The third carrier gas supply unit 7 may be connected to the third gas supply unit 4. An arrow illustrated by a solid line in FIG. 2 schematically illustrates a schematic flow direction of the third carrier gas.

The third carrier gas supply unit 7 may be connected to the third gas supply unit 4 with being apart from the chamber 100. The third carrier gas supply unit 7 may perform a function of storing the third carrier gas and supplying the third carrier gas to the third gas supply unit 4. The third carrier gas supply unit 7 may be apart from the chamber 100 by a shorter distance than the second carrier gas supply unit 6.

The third carrier gas supply unit 7 may supply the third carrier gas so that the third carrier gas is supplied to the third gas supply unit 4 at a flow rate which is lower than that of the second carrier gas. That is, the second carrier gas may flow at a flow rate which is higher than that of the third carrier gas. A length of the arrow illustrated by the solid line in FIG. 2 schematically illustrates a schematic magnitude of a flow rate of the third carrier gas.

Referring to FIGS. 1 and 2, the third carrier gas supply unit 7 may include a third control module 71. The third control module 71 adjusts a flow rate of the third carrier gas. The third control module 71 may be disposed at an outlet of the third carrier gas supply unit 7. The third control module 71 may adjust a flow rate of the third carrier gas, thereby adjusting a flow force of the third gas. The third control module 71 may be wholly implemented as a valve.

Referring to FIGS. 1 and 2, the substrate processing apparatus 1 according to the present inventive concept may include a first gas flow path 8 and a second gas flow path 9.

The first gas flow path 8 is connected to the first gas supply unit 2. The first gas flow path 8 may be implemented as a pipe through which the first gas and the first carrier gas flow. The first gas flow path 8 may be formed so that a cross-sectional area thereof has a circular shape with respect to a direction vertical to a direction in which the first gas and the first carrier gas flow.

The second gas flow path 9 is connected to the second gas supply unit 3. The second gas flow path 9 may be implemented as a pipe through which the second gas and the second carrier gas flow. The second gas flow path 9 may be formed so that a cross-sectional area thereof has a circular shape with respect to a direction vertical to a direction in which the second gas and the second carrier gas flow.

The second gas flow path 9 may be apart from the first gas flow path 8. The second gas flow path 9 may be disposed closer to the chamber 100 than the first gas flow path 8. That is, the first gas flow path 8 through which the first carrier gas flows may be farther away from the chamber 100 than the second gas flow path 9 through which the second carrier gas flows. The second gas flow path 9 may be formed to have the same length as that of the first gas flow path 8.

The second gas flow path 9 may be formed to have an area which is less than that of the first gas flow path 8. Accordingly, the substrate processing apparatus 1 according to the present inventive concept may be implemented so that the first carrier gas flows at a flow rate which is higher than that of the second carrier gas.

Referring to FIGS. 1 and 2, the substrate processing apparatus 1 according to the present inventive concept may include a third gas flow path 10.

The third gas flow path 10 is connected to the third gas supply unit 4. The third gas flow path 10 may be implemented as a pipe through which the third gas and the third carrier gas flow. The third gas flow path 10 may be formed so that a cross-sectional area thereof has a circular shape with respect to a direction vertical to a direction in which the third gas and the third carrier gas flow.

The third gas flow path 10 may be apart from each of the second gas flow path 9 and the first gas flow path 8. The third gas flow path 10 may be disposed closer to the chamber 100 than the second gas flow path 9. That is, the second gas flow path 9 through which the second carrier gas flows may be farther away from the chamber 100 than the third gas flow path 10 through which the third carrier gas flows. The third gas flow path 10 may be formed to have the same length as that of the second gas flow path 9.

The third gas flow path 10 may be formed to have an area which is less than that of the second gas flow path 9. Accordingly, the substrate processing apparatus 1 according to the present inventive concept may be implemented so that the second carrier gas flows at a flow rate which is higher than that of the third carrier gas.

Referring to FIGS. 2 and 3, the substrate processing apparatus 1 according to the present inventive concept may include the first carrier gas and the first gas (hereinafter referred to as ‘first gases’), the second carrier gas and the second gas (hereinafter referred to as ‘second gases’), and the third carrier gas and the third gas (hereinafter referred to as ‘third gases’). To this end, the first gas supply unit 2 and the second gas supply unit 3 may respectively include the following configurations.

The first gas supply unit 2 may include a first injection member 21 and a first injection hole 22.

The first injection member 21 may inject the first gases into the chamber 100. The first injection member 21 may be connected to each of the first gas supply unit 2 and the first gas flow path 8. The first gases stored in the first gas supply unit 2 may be injected into the first gas flow path 8 through the first injection member 21.

The first injection hole 22 is formed in the first injection member 21. The first injection hole 22 may be formed to pass through the first injection member 21. The first gases may pass through the first injection hole 22 and may be injected into the first gas flow path 8. The first injection hole 22 may be formed in the first injection member 21 so that an area thereof is adjustable.

The second gas supply unit 3 may include a second injection member 31 and a second injection hole 32.

The second injection member 31 may inject the second gases into the chamber 100. The second injection member 31 may be connected to each of the second gas supply unit 3 and the second gas flow path 9. The second gases stored in the second gas supply unit 3 may be injected into the second gas flow path 9 through the second injection member 31. The second injection member 31 may be disposed closer to the chamber 100 than the first injection member 21.

The second injection hole 32 is formed in the second injection member 31. The second injection hole 32 may be formed to pass through the second injection member 31. The second gases may pass through the second injection hole 32 and may be injected into the second gas flow path 9. The second injection hole 32 may be formed in the second injection member 31 so that an area thereof is adjustable. The second injection hole 32 may be disposed closer to the chamber 100 than the first injection hole 22.

The second injection hole 32 may be formed to have a size which is less than that of the first injection hole 22. Accordingly, the substrate processing apparatus 1 according to the present inventive concept may be implemented so that the first gases flow at a flow rate which is higher than that of each of the second gases.

The third gas supply unit 4 may include a third injection member 41 and a third injection hole (not shown).

The third injection member 41 may inject the third gases into the chamber 100. The third injection member 41 may be connected to each of the third gas supply unit 4 and the third gas flow path 10. The third gases stored in the third gas supply unit 4 may be injected into the third gas flow path 10 through the third injection member 41. The third injection member 41 may be disposed closer to the chamber 100 than the second injection member.

The third injection hole is formed in the third injection member 41. The third injection hole may be formed to pass through the third injection member 41. The third gases may pass through the third injection hole and may be injected into the third gas flow path 10. The third injection hole may be formed in the third injection member 41 so that an area thereof is adjustable. The third injection hole may be disposed closer to the chamber 100 than the second injection hole.

The third injection hole may be formed to have a size which is less than that of the second injection hole. Accordingly, the substrate processing apparatus 1 according to the present inventive concept may be implemented so that the second gases flow at a flow rate which is higher than that of each of the third gases.

Referring to FIGS. 1 to 5, the substrate processing apparatus 1 according to the present inventive concept may include a common flow path 11.

The common flow path 11 is connected to each of the first gas flow path 8, the second gas flow path 9, and the chamber 100. When the substrate processing apparatus 1 according to the present inventive concept further includes the third gas flow path 10, the common flow path 11 may be connected to each of the first gas flow path 8, the second gas flow path 9, the third gas flow path 10, and the chamber 100. The common flow path 11 may be implemented as a pipe through which the first gas, the first carrier gas, the second gas, the second carrier gas, the third gas, and the third carrier gas flow.

Referring to FIGS. 1 to 5, the common flow path 11 may include a first common flow path 111, a second common flow path 112, and a third common flow path 113.

The first common flow path 111 is connected to the first gas flow path 8. The first common flow path 111 may be connected to each of the first gas flow path 8 and the second common flow path 112. The first common flow path 111 may be implemented as a pipe through which the first gas and the first carrier gas flow. The first carrier gas supplied by the first carrier gas supply unit 5 may sequentially flow through the first gas supply unit 2, the first gas flow path 8, the first common flow path 111, the second common flow path 112, and the third common flow path 113 and may be supplied to the chamber 100. An arrow illustrated by a dotted line in FIG. 4 schematically illustrates a schematic flow direction of the first carrier gas. The first gas supplied by the first gas supply unit 2 may sequentially flow through the first gas flow path 8, the first common flow path 111, the second common flow path 112, and the third common flow path 113 and may be supplied to the chamber 100.

A first connection point CP1 may be formed at a portion at which the first common flow path 111 is connected to the first gas flow path 8. The first connection point CP1, as illustrated in FIG. 4, may be a portion of the common flow path 11 where a flow direction of each of the first carrier gas and the first gas is changed.

The second common flow path 112 is connected to the second gas flow path 9. The second common flow path 112 may be connected to each of the second gas flow path 9, the first common flow path 111, and the third common flow path 113. The second common flow path 112 may be implemented as a pipe through which the second gas and the second carrier gas flow. The second carrier gas supplied by the second carrier gas supply unit 6 may sequentially flow through the second gas supply unit 3, the second gas flow path 9, the second common flow path 112, and the third common flow path 113 and may be supplied to the chamber 100. An arrow illustrated by a one-dot-dashed line in FIG. 4 schematically illustrates a schematic flow direction of the second carrier gas. The second gas supplied by the second gas supply unit 3 may sequentially flow through the second gas flow path 9, the second common flow path 112, and the third common flow path 113 and may be supplied to the chamber 100.

Referring to FIGS. 4 and 5, the substrate processing apparatus 1 according to the present inventive concept may be implemented so that the first carrier gas sequentially flows through the first common flow path 111 and the second common flow path 112. To this end, the first common flow path 111 may be farther away from the chamber 100 than the second common flow path 112. Therefore, comparing with a comparative example where the first carrier gas does not sequentially flow through the first common flow path 111 and the second common flow path 112, the substrate processing apparatus 1 according to the present inventive concept may be implemented so that first carrier gas increases a flow force of the second gas. This will be described below in detail with reference to the accompanying drawings.

First, FIG. 5 illustrates a comparative example where the first carrier gas does not sequentially flow through the first common flow path 111 and the second common flow path 112. In the comparative example, a flow direction of the first carrier gas may be opposite to a flow direction of the second carrier gas. Therefore, in the comparative example, the first carrier gas having a relatively high flow rate may reversely flow to and penetrate into the second common flow path 112, and thus, may push the second carrier gas toward the second gas supply unit 3. Therefore, the comparative example may decrease the degree to which the second carrier gas increases a flow-enabled distance of the second gas. Furthermore, in the comparative example, a flow direction of the first carrier gas may be opposite to a flow direction of the second gas, thereby decreasing the amount of the second gas reaching the chamber 100 by using the first carrier gas. Accordingly, the comparative example may decrease the amount of the second gas applied to the processing process. A length of an arrow illustrated by a dotted line and a length of an arrow illustrated by a one-dot-dashed line in FIG. 5 schematically illustrate a magnitude of a flow rate of the first carrier gas and a magnitude of a flow rate of the second carrier gas, respectively.

Next, FIG. 4 illustrates an embodiment where the first carrier gas flows sequentially through the first common flow path 111 and the second common flow path 112. In an embodiment, a flow direction of the first carrier gas may be the same as a flow direction of the second carrier gas. Therefore, in an embodiment, the first carrier gas having a relatively high flow rate may complement the second carrier gas to push the second gas toward the chamber 100. Also, an embodiment is implemented so that a flow direction of the first carrier gas is the same as a flow direction of the second gas in the second common flow path 112. Therefore, an embodiment may be implemented so that the first carrier gas increases a flow-enabled distance of the second gas as well as the first gas. Accordingly, an embodiment may increase the amount of the second gas applied to the processing process, thereby increasing the amount of mixed process gases in the chamber 100. A length of an arrow illustrated by a dotted line and a length of an arrow illustrated by a one-dot-dashed line in FIG. 4 schematically illustrate a magnitude of a flow rate of the first carrier gas and a magnitude of a flow rate of the second carrier gas, respectively.

The second common flow path 112 and the first common flow path 111 may be formed to extend in the same direction. Accordingly, the substrate processing apparatus 1 according to the present inventive concept may be implemented so that a flow path of the first carrier gas in the common flow path 11 is not changed. FIG. 4 schematically illustrates an example where the second common flow path 112 is rectilinearly connected to the first common flow path 111.

The second common flow path 112 may be formed to be longer than the first common flow path 111. Accordingly, the substrate processing apparatus 1 according to the present inventive concept may increase a flow time of the first carrier gas in the second common flow path 112, thereby increasing a flow force of the second gas based on the first carrier gas. The second common flow path 112 may be formed to have the same length as that of the first common flow path 111.

A second connection point CP2 may be formed at a portion at which the second common flow path 112 is connected to the second gas flow path 9. The second connection point CP2, as illustrated in FIG. 4, may correspond to a point at which a flow direction of each of the second carrier gas and the second gas is changed and may be a portion of the common flow path 11 where the second carrier gas and the first carrier gas respectively meet the second gas and the first gas. In the substrate processing apparatus 1 according to the present inventive concept, the first carrier gas may have a flow rate which is higher than that of the second carrier gas, thereby implementing a preventive force for preventing the second carrier gas from diffusing and penetrating from the second connection point CP2 to the first connection point CP1.

The second connection point CP2 may be disposed apart from the first connection point CP1. The second connection point CP2 may be disposed closer to the chamber 100 than the first connection point CP1. The first carrier gas may sequentially flow through the first connection point CP1 and the second connection point CP2.

The third common flow path 113 is connected to the third gas flow path 10. The third common flow path 113 may be connected to each of the second common flow path 112, the third gas flow path 10, and the chamber 100. The third common flow path 113 may be implemented as a pipe through which the third gas and the third carrier gas flow. The third carrier gas supplied by the third carrier gas supply unit 7 may sequentially flow through the third gas supply unit 4, the third gas flow path 10, and the third common flow path 113 and may be supplied to the chamber 100. An arrow illustrated by a solid line in FIG. 2 schematically illustrates a schematic flow direction of the third carrier gas. The third gas supplied by the third gas supply unit 4 may sequentially flow through the third gas flow path 10 and the third common flow path 113 and may be supplied to the chamber 100.

Referring to FIG. 2, the substrate processing apparatus 1 according to the present inventive concept may be implemented so that the first carrier gas sequentially flows through the first common flow path 111, the second common flow path 112, and the third common flow path 113. To this end, the first common flow path 111 may be disposed farther away from the chamber 100 than the second common flow path 112. Therefore, comparing with a comparative example where the first carrier gas does not sequentially flow through the first common flow path 111, the second common flow path 112, and the third common flow path 113, the substrate processing apparatus 1 according to the present inventive concept may be implemented so that first carrier gas increases a flow force of each of the second gas and the third gas. Accordingly, the substrate processing apparatus 1 according to the present inventive concept may increase the amount of the second gas and the third gas applied to the processing process, thereby increasing the amount of mixed process gases in the chamber 100.

The third common flow path 113, the second common flow path 112, and the first common flow path 111 may be formed to extend in the same direction. Accordingly, the substrate processing apparatus 1 according to the present inventive concept may be implemented so that a flow path of the first carrier gas in the common flow path 11 is not changed. The third common flow path 113, the second common flow path 112, and the first common flow path 111 may be rectilinearly connected to one another.

The third common flow path 113 may be formed to be longer than each of the second common flow path 112 and the first common flow path 111. The third common flow path 113, the second common flow path 112, and the first common flow path 111 may all be formed to have the same length.

A third connection point CP3 may be formed at a portion at which the third common flow path 113 is connected to the third gas flow path 10. The third connection point CP3, as illustrated in FIG. 2, may correspond to a point at which a flow direction of each of the third carrier gas and the third gas is changed and may be a portion of the common flow path 11 where the third carrier gas, the second carrier gas, and the first carrier gas respectively meet the third gas, the second gas, and the first gas. In the substrate processing apparatus 1 according to the present inventive concept, each of the first carrier gas and the second carrier gas may have a flow rate which is higher than that of the third carrier gas, thereby implementing a preventive force for preventing the third carrier gas from diffusing and penetrating from the third connection point CP3 to the second connection point CP2.

The third connection point CP3 may be disposed apart from each of the second connection point CP2 and the first connection point CP1. The third connection point CP3 may be disposed closer to the chamber 100 than the second connection point CP2. The first carrier gas may sequentially flow through the first connection point CP1, the second connection point CP2, and the third connection point CP3.

Hereinabove, the substrate processing apparatus 1 according to the present inventive concept has been described as including three gas supply units and three carrier gas supply units, but this is merely an example and the substrate processing apparatus 1 according to the present inventive concept may include four or more gas supply units and four or more carrier gas supply units.

To this end, the substrate processing apparatus 1 according to the present inventive concept may include N (where N is an integer of 3 or more) number of gas supply units, which supply the chamber 100 with process gases having different vapor pressures, and N number of carrier gas supply units which respectively supply a carrier gas to the gas supply units so as to increase a flow force of each of the process gases. A first gas supply unit 20 among the gas supply units may supply the chamber 100 with a first gas having a vapor pressure which is lower than that of a second gas supply unit 20′ among the gas supply units and may be apart from the chamber 100 by a distance which is longer than the second gas supply unit 20′. A first carrier gas supply unit 30 among the carrier gas supply units may supply the first gas supply unit 20 with a first carrier gas having a flow rate which is higher than that of a second carrier gas supply unit 30′ among the carrier gas supply units.

FIG. 6 illustrates an embodiment where a substrate processing apparatus 1 according to the present inventive concept includes four gas supply units 20, 20′, 20″, and 20′″ and four carrier gas supply units 30, 30′, 30″, and 3′″. In this case, the substrate processing apparatus 1 according to the present inventive concept may include four gas flow paths 40, 40′, 40″, and 40′″ respectively connected to the gas supply units 20, 20′, 20″, and 20′″ and one common flow path 50 connected to the gas flow paths 40, 40′, 40″, and 40′″.

The present inventive concept described above are not limited to the above-described embodiments and the accompanying drawings and those skilled in the art will clearly appreciate that various modifications, deformations, and substitutions are possible without departing from the scope and spirit of the invention.

1. A substrate processing apparatus comprising:
a chamber providing a process space for a substrate;
a first gas supply unit for supplying the chamber with a first gas having a first vapor pressure;
a second gas supply unit for supplying the chamber with a second gas having a second vapor pressure which is higher than the first vapor pressure; and
a third gas supply unit for supplying the chamber with a third gas having a third vapor pressure which is higher than the second vapor pressure.

2. The substrate processing apparatus of claim 1, wherein
a length of a gas flow path connected from the first gas supply unit to the chamber is set to be longer than a length of a gas flow path connected from the second gas supply unit to the chamber, and
the length of the gas flow path connected from the second gas supply unit to the chamber is set to be longer than a length of a gas flow path connected from the third gas supply unit to the chamber.

3. The substrate processing apparatus of claim 1, comprising:
a substrate supporting unit installed in an inner process space of the chamber to support the substrate; and
a gas distribution unit distributing a process gas from an upper portion of the process space to the substrate supporting unit.

4. The substrate processing apparatus of claim 1, wherein
the first gas comprises indium,
the second gas comprises zinc, and
the third gas comprises gallium.

5. A gas supply apparatus for a substrate processing apparatus, the gas supply apparatus comprising:
a first gas supply unit for supplying a first gas to a chamber providing a process space for a substrate;
a second gas supply unit for supplying the chamber with a second gas having a vapor pressure which is higher than the first gas;
a first carrier gas supply unit supplying a first carrier gas to the first gas supply unit to increase a flow force of the first gas; and
a second carrier gas supply unit supplying a second carrier gas to the second gas supply unit to increase a flow force of the second gas,
wherein
the first carrier gas supply unit supplies the first carrier gas so that the first carrier gas is supplied to the first gas supply unit at a flow rate which is higher than the second carrier gas, and
the first gas supply unit is apart from the chamber by a longer distance than a distance by which the second gas supply unit is apart from the chamber.

6. The gas supply apparatus of claim 5, further comprising:
a first gas flow path connected to the first gas supply unit; and
a second gas flow path connected to the second gas supply unit,
wherein the first gas flow path is formed to have an area which is greater than the second gas flow path, so that the first carrier gas flows at a flow rate which is higher than the second carrier gas.

7. The gas supply apparatus of claim 5, wherein
the first gas supply unit comprises a first injection member for injecting the first gas and the first carrier gas into the chamber and a first injection hole formed in the first injection member,
the second gas supply unit comprises a second injection member for injecting the second gas and the second carrier gas into the chamber and a second injection hole formed in the second injection member, and
the first injection hole is formed to have a size which is greater than the second injection hole.

8. (canceled)

9. The gas supply apparatus of claim 5, further comprising:
a first gas flow path connected to the first gas supply unit; and
a second gas flow path connected to the second gas supply unit,
wherein the first gas flow path is disposed farther away from the chamber than the second gas flow path.

10. The gas supply apparatus of claim 5, wherein the first carrier gas supply unit comprises a first control module adjusting a flow rate of the first carrier gas.

11. The gas supply apparatus of claim 5, further comprising:
a first gas flow path connected to the first gas supply unit;
a second gas flow path connected to the second gas supply unit; and
a common flow path connected to each of the first gas flow path, the second gas flow path, and the chamber,
wherein the common flow path comprises a first common flow path connected to the first gas flow path and a second common flow path connected to the second gas flow path.

12. A gas supply apparatus for a substrate processing apparatus, the gas supply apparatus comprising:
N (where N is an integer of 3 or more) number of gas supply units supplying process gases having different vapor pressures to a chamber providing a process space for a substrate; and
N number of carrier gas supply units respectively supplying a carrier gas to the gas supply units to increase flow forces of the process gases,
wherein
a first gas supply unit of the N gas supply units supplies the chamber with a first gas, having a vapor pressure which is lower than a second gas supply unit of the N gas supply units, and is apart from the chamber by a distance which is longer than the second gas supply unit, and a first carrier gas supply unit of the N carrier gas supply units supplies the first gas supply unit with a first carrier gas having a flow rate which is higher than a second carrier gas supply unit of the N carrier gas supply units.

13. The gas supply apparatus of claim 12, further comprising:
a first gas flow path connected to the first gas supply unit; and
a second gas flow path connected to the second gas supply unit,
wherein the first gas flow path is disposed farther away from the chamber than the second gas flow path.

14. The gas supply apparatus of claim 12, wherein the first carrier gas supply unit comprises a first control module adjusting a flow rate of the first carrier gas.

15. The gas supply apparatus of claim 12, further comprising:
a first gas flow path connected to the first gas supply unit;
a second gas flow path connected to the second gas supply unit; and
a common flow path connected to each of the first gas flow path, the second gas flow path, and the chamber,
wherein the common flow path comprises a first common flow path connected to the first gas flow path and a second common flow path connected to the second gas flow path.
